(19) United States
(12) Patent Application Publication
(10) Pub. No.: US 2024/0243724 A1
(43) Pub. Date: Jul. 18, 2024

(54) SURFACE ACOUSTIC WAVE DEVICE STRUCTURE AND ELECTRONIC APPARATUS

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/304,765

(22) Filed: Apr. 21, 2023

(30) Foreign Application Priority Data
Jan. 17, 2023 (CN) 202310066387.X

(51) Int. Cl. H03H 9/25; H03H 9/02

(52) U.S. Cl. CPC H03H 9/25; H03H 9/02574; H03H 9/02897

(57) ABSTRACT

Disclosed are a surface acoustic wave device structure and an electronic apparatus. The surface acoustic wave device structure includes a substrate, a support structure layer, a single crystal piezoelectric layer and an interdigital transducer which are stacked sequentially, the support structure layer includes at least one periodic structure, each of the at least one periodic structure includes at least one period, and each of the includes period includes a first periodic layer and a second periodic layer which are stacked sequentially, a material of the first periodic layer is AlScN, and the first periodic layer is disposed on one side of the second periodic layer away from the substrate.

### CROSS-REFERENCE TO RELATED APPLICATIONS

This application claims priority to the Chinese Patent Application No. 202310066387.X filed on Jan. 17, 2023, the entire contents of which are hereby incorporated by reference.

### TECHNICAL FIELD

This application relates to the field of semiconductor technologies, and in particular, to a surface acoustic wave device structure and an electronic apparatus.

### BACKGROUND

At present, Surface Acoustic Wave (SAW) devices have been widely used in today's increasingly complex social communication systems, especially in the mainstream 5G communication era, the surface acoustic wave devices with high-frequency and low-cost are widely used in various handheld terminal devices.

### SUMMARY

Embodiments of the present application provide a surface acoustic wave device structure and an electronic apparatus to solve the technical problems that a single crystal piezoelectric wafer used in a surface acoustic wave device is easily broken.

According to one aspect of the present application, an embodiment of the present application provides a surface acoustic wave device structure, including: a substrate, a support structure layer, a single crystal piezoelectric layer and an interdigital transducer which are stacked sequentially, the support structure layer includes at least one periodic structure, each of the at least one periodic structure includes at least one period, and each of the at least one period includes a first periodic layer and a second periodic layer which are stacked sequentially, a material of the first periodic layer is AlScN, and the first periodic layer is disposed on one side of the second periodic layer away from the substrate.

As an optional embodiment, a material of the second periodic layer is at least one of GaN, AlInN and AlInGaN.

As an optional embodiment, a thickness of the second periodic layer ranges from 10 nm to 30 nm.

As an optional embodiment, a material of the first periodic layer is Al₁₋ₐScₐN, and a Sc component ranges from 0.15 to 0.25.

As an optional embodiment, a lattice constant of the first periodic layer ranges from 3.17 to 3.21.

As an optional embodiment, a lattice constant of the first periodic layer matches that of the second periodic layer.

As an optional embodiment, a thickness of the first periodic layer ranges from 10 nm to 30 nm.

As an optional embodiment, in a same periodic structure, a thickness of the first periodic layer is greater than that of the second periodic layer.

As an optional embodiment, a thickness of the n^{th} periodic structure is less than that of the (n+1)^{th} periodic structure along a direction away from the substrate, and the n is an integer greater than or equal to 1.

As an optional embodiment, a thickness of the first periodic layer of the n^{th} periodic structure is less than that of the first periodic layer of the (n+1)^{th} periodic structure, and a thickness of the second periodic layer of the n^{th} periodic structure is greater than that of the second periodic layer of the (n+1)^{th} periodic structure along the direction away from the substrate.

As an optional embodiment, the thickness of the first periodic layer of the n^{th} periodic structure is less than that of the first periodic layer of the (n+1)^{th} periodic structure within a range of 0 nm to 10 nm; the thickness of the second periodic layer of the n^{th} periodic structure is greater than that of the second periodic layer of the (n+1)^{th} periodic structure within a range of 0 nm to 10 nm.

As an optional embodiment, each of the at least one period further includes a third periodic layer, and the third periodic layer is disposed between the first periodic layer and the second periodic layer.

As an optional embodiment, a material of the third periodic layer is at least one of AlInN and AlInGaN, and a material component of the third periodic layer is different from that of the second periodic layer.

As an optional embodiment, a thickness of the third periodic layer is less than that of the first periodic layer, and the thickness of the third periodic layer is greater than that of the second periodic layer.

As an optional embodiment, a lattice constant of the third periodic layer matches that of each periodic layer of both the first periodic layer and the second periodic layer.

As an optional embodiment, the substrate is any one of a silicon substrate, a SOI substrate and a silicon substrate of which a surface has silicon dioxide.

As an optional embodiment, the single crystal piezoelectric layer is made of scandium-doped aluminum nitride material.

As an optional embodiment, a thickness of the single crystal piezoelectric layer is greater than 500 nm.

According to another aspect of the present application, an embodiment of the present application provides an electronic apparatus, including: a surface acoustic wave device, the surface acoustic wave device has a surface acoustic wave device structure, including: a substrate, a support structure layer, a single crystal piezoelectric layer; and an interdigital transducer which are stacked sequentially, and the support structure layer includes at least one periodic structure, each of the at least one periodic structure includes at least one period, and each of the at least one period includes a first periodic layer and a second periodic layer which are stacked sequentially, a material of the first periodic layer is AlScN, and the first periodic layer is disposed on one side of the second periodic layer away from the substrate.

As an optional embodiment, each of the at least one period further includes a third periodic layer, and the third periodic layer is disposed between the first periodic layer and the second periodic layer.

### BRIEF DESCRIPTION OF THE DRAWINGS

FIG. 1 is a schematic diagram of a surface acoustic wave device structure according to an embodiment of the present application.

FIG. 2 is a schematic diagram of a surface acoustic wave device structure according to another embodiment of the present application.

FIG. 3 is a schematic diagram of a surface acoustic wave device structure according to another embodiment of the present application.

FIG. 4 is a schematic diagram of a surface acoustic wave device structure according to another embodiment of the present application.

### DETAILED DESCRIPTION OF THE EMBODIMENTS

The following may clearly and completely describe the technical solutions in the embodiments of the application with reference to the drawings in the embodiments of the application. Apparently, the described embodiments are only some, not all embodiments of the application. Based on the embodiments in this application, all other embodiments obtained by a person of ordinary skill in the art without making creative efforts belong to the protection scope of this application.

A piezoelectric substrate used in a surface acoustic wave device is usually formed by bonding and thinning a silicon substrate and a single crystal piezoelectric wafer. However, a material of the single crystal piezoelectric wafer is very brittle and easily broken during semiconductor process, and therefore, a process menu requires a special design, which reduces production efficiency.

In order to solve the technical problems that the single crystal piezoelectric wafer used in the surface acoustic wave device is easily broken, this application provides the surface acoustic wave device structure, including the substrate, the support structure layer, the single crystal piezoelectric layer and the interdigital transducer which are stacked sequentially. The support structure layer includes the at least one periodic structure, and each of the at least one periodic structure includes the at least one period. Each of the at least one period includes the first periodic layer and the second periodic layer which are sequentially stacked. The material of the first periodic layer is AlScN, and the first periodic layer is disposed on one side of the second periodic layer away from the substrate. According to the surface acoustic wave device structure of this application, the support structure layer is disposed between the single crystal piezoelectric layer and the substrate, so that on the one hand, a stress caused by the lattice mismatch between the single crystal piezoelectric layer and the substrate may be released, to avoid fracture of the single crystal piezoelectric layer, and on the other hand, since the support structure layer may play the role of acoustic wave reflection, when the acoustic wave in the single crystal piezoelectric layer is transmitted to the support structure layer, the acoustic wave is reflected back into the single crystal piezoelectric layer, to reduce energy loss of the acoustic wave.

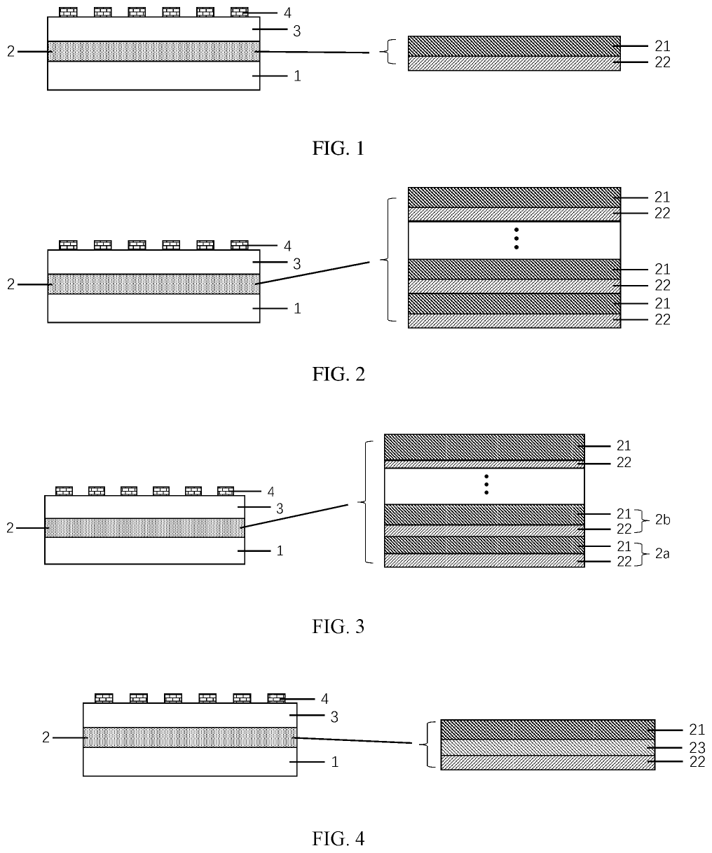

The surface acoustic wave device structure mentioned in this application may be further illustrated below with reference to FIG. 1 to FIG. 4.

FIG. 1 is a schematic diagram of a surface acoustic wave device structure according to an embodiment of the present application. As shown in FIG. 1, the surface acoustic wave device structure includes a substrate 1, a support structure layer 2, a single crystal piezoelectric layer 3, and an interdigital transducer 4 which are stacked sequentially. The support structure layer 2 includes at least one periodic structure, and each periodic structure includes at least one period. Each period includes a first periodic layer 21 and a second periodic layer 22 which are stacked sequentially, and the first periodic layer 21 is disposed on one side of the second periodic layer 22 away from the substrate 1.

In this embodiment, the substrate 1 is one of a silicon substrate, a SOI substrate and a silicon substrate of which a surface has silicon dioxide. In a Silicon-On-Insulator (SOI) substrate, a buried oxide layer is disposed between a top silicon and a back substrate. The SOI substrate has many advantages, such as eliminating a latch-up effect and reducing a parasitic capacitance, improving an operating speed and reducing power consumption.

In this embodiment, the support structure layer 2 includes the at least one periodic structure, each periodic structure includes the at least one period, and each period includes the first periodic layer 21 and the second periodic layer 22 which are sequentially stacked. A material of the first periodic layer 21 is AlScN, and a material of the second periodic layer 22 is at least one of GaN, AlInN and AlInGaN. The material of the first periodic layer 21 is Al₁₋ₐScₐN, and a Sc component of ranges from 0.15 to 0.25. A lattice constant of the first periodic layer 21 ranges from 3.17 to 3.21. The lattice constant of the first periodic layer 21 matches that of the second periodic layer 22, which is beneficial to release a stress of the support structure layer 2 and substrate 1. Compared with the periodic structure formed by two materials of AlN and AlScN, a lattice constant of the two materials does not match, and there is large stress in the device structure, and however, in this application, the periodic structure is formed by two materials of AlScN and at least one of GaN, AlInN, and AlInGaN, a lattice constant of the two materials matches, so that a stress of the support structure layer 2 is released better, which is conducive to improving a crystal quality of the single crystal piezoelectric layer 3 grown on the support structure layer 2, and without stress problems, makes the single crystal piezoelectric layer 3 not easy to broke and warp. In a same periodic structure of the support structure layer 2, a thickness of the first periodic layer 21 is greater than that of the second periodic layer 22 (shown in FIG. 1), which may improve a piezoelectric performance of an overall device structure.

In this embodiment, growth of the support structure layer 2 may be in situ growth, and the support structure layer 2 may also be prepared by Atomic Layer Deposition (ALD), Chemical Vapor Deposition (CVD), Molecular Beam Epitaxy (MBE), Plasma Enhanced Chemical Vapor Deposition (PECVD), Low Pressure Chemical Vapor Deposition (LPCVD), Metal-Organic Chemical Vapor Deposition (MOCVD), or a combination thereof.

In this embodiment, as for the surface acoustic wave device, in order to achieve the goals of high frequency and low insertion loss, etc., it is necessary to continuously improve the piezoelectric performance of a piezoelectric material. Since the piezoelectric performance of an AlN piezoelectric film doped with Sc is significantly improved compared with that of an AlN piezoelectric film, an AlN material doped with the Sc may be used as the material of the single crystal piezoelectric layer 3 to improve a performance of a SAW resonator. In the Sc-doped AlN material, some Al atoms are replaced by Sc atoms to form scandium nitride (ScN). The scandium nitride is a nonpolar nitride with a rack salt structure, and aluminum nitride is a polar III-V nitride with a wurtzite structure. After the Sc is doped in the AlN material, a transition region between the wurtzite structure and the rack salt structure is formed, thereby improving a piezoelectric coefficient of an aluminum nitride film. Proper amount of Sc doping may increase the piezoelectric coefficient of the AlN film within a range of 100% to 500%. The single crystal piezoelectric layer 3 is (002) oriented, and the thickness of the single crystal piezoelectric layer 3 is greater than 500 nm, which ensures its good piezoelectric performance.

In this embodiment, an electrode material of the interdigital transducer 4 is aluminum, gold, copper or copper-aluminum alloy material. A piezoelectric effect adopted by an input interdigital transducer is used to excite an acoustic wave in the single crystal piezoelectric layer 3 to complete electro-acoustic conversion, and then the acoustic wave propagates to an output interdigital transducer, an inverse piezoelectric effect adopted by an output interdigital transducer is used to receive the acoustic wave to complete acoustic-electric conversion.

FIG. 2 is a schematic diagram of a surface acoustic wave device structure according to another embodiment of the present application.

The content of the embodiment in FIG. 2 is substantially the same as that of the embodiment in FIG. 1, and the differences are that, as shown in FIG. 2, the periodic structure of the support structure layer 2 has a plurality of periods. The plurality of periods of the periodic structure are dispose in the support structure layer 2, the stress, caused by the lattice mismatch between the support structure layer 2 and the substrate 1, is gradually released, thereby further improving the crystal quality of the single crystal piezoelectric layer 3 above the support structure layer 2. The plurality of periods of the support structure layer 2 may also play the role of the acoustic wave reflection. When the acoustic wave in the single crystal piezoelectric layer 3 is transmitted to the support structure layer 2, the acoustic wave is reflected back into the single crystal piezoelectric layer 3, which reduces the energy loss of the acoustic wave, and improves Figure Of Merit (FOM) of the device and an electromechanical coupling coefficient.

FIG. 3 is a schematic diagram of a surface acoustic wave device structure according to another embodiment of the present application.

The content of the embodiment in FIG. 3 is roughly the same as that of the embodiment in FIG. 1, the differences are that, as shown in FIG. 3, the support structure layer 2 has multiple periodic structures (for example, 2a, 2b, . . . ), and along a direction away from the substrate 1, a thickness of the n^{th} periodic structure is less than that of the (n+1)^{th} periodic structure, the n is an integer greater than or equal to 1. Considering that the closer to the substrate in an epitaxial structure, the greater the dislocation density, and therefore, the thickness of the n^{th} periodic structure is arranged to be smaller than that of the (n+1)^{th} periodic structure in the direction away from the substrate 1, so that the periodic structure with relatively low dislocation density has a relatively large thickness. The farther the periodic structure away from substrate 1, the more effectively the stress in the overall epitaxial structure can be balanced, and the better the crystal quality of the periodic structure farther away from substrate 1 is guaranteed, so that the crystal quality of the single crystal piezoelectric layer 3 above the support structure layer 2 is improved, which makes it less prone to be broke and warp. The support structure layer 2 with the multiple periodic structure may also play the role of the acoustic wave reflection, and when the acoustic wave in the single crystal piezoelectric layer 3 is transmitted to the support structure layer 2, the acoustic wave is reflected back into the single crystal piezoelectric layer 3, which reduces the energy loss of the acoustic wave and improves the FOM of the device and the electromechanical coupling coefficient.

In this embodiment, along the direction away from the substrate 1, the thickness of the first periodic layer 21 of the n^{th} periodic structure is less than that of the first periodic layer 21 of the (n+1)^{th} periodic structure, and the thickness of the second periodic layer 22 of the n^{th} periodic structure is greater than that of the second periodic layer 22 of the (n+1)^{th} periodic structure. The thickness of the first periodic layer 21 ranges from 10 nm to 30 nm, and the thickness of the first periodic layer 21 of the n^{th} periodic structure is less than that of the first periodic layer 21 of the (n+1)^{th} periodic structure within a range of 0 nm to 10 nm; the thickness of the second periodic layer 22 ranges from 10 nm to 30 nm, and the thickness of the second periodic layer 22 of the n^{th} periodic structure is greater than that of the second periodic layer 22 of the (n+1)^{th} periodic structure within a range of 0 nm to 10 nm. Along the direction away from substrate 1, the thickness of the first periodic layer 21 is increased, so that the piezoelectric performance of the device structure is improved.

The embodiment in FIG. 4 is substantially the same as the embodiment in FIG. 1, the differences are that, as shown in FIG. 3, the support structure layer 2 further includes a third periodic layer 23, the material of the third periodic layer 23 is at least one of AlInN and AlInGaN, and a material component of the third periodic layer is different from that of the second periodic layer 22. The third periodic layer 23 is disposed between the first periodic layer 21 and the second periodic layer 22, a thickness of the third periodic layer 23 is less than that of the first periodic layer 21, and the thickness of the third periodic layer 23 is greater than the thickness of the second periodic layer 22. A lattice constant of the third periodic layer 23 also matches that of both the first periodic layer 21 and the second periodic layer 22, and the third periodic layer 23 is disposed to further release the stress and prevent the single crystal piezoelectric layer 3 from broking.

This application provides the surface acoustic wave device structure, including the substrate, the support structure layer, the single crystal piezoelectric layer and the interdigital transducer which are stacked sequentially. The support structure layer includes at least one periodic structure, and each of the at least one periodic structure includes at least one period, and each of the at least one period includes a first periodic layer and a second periodic layer which are stacked sequentially. The material of the first periodic layer is AlScN, and the first periodic layer is disposed on one side of the second periodic layer away from the substrate. According to the surface acoustic wave device structure of this application, the support structure layer is disposed between the single crystal piezoelectric layer and the substrate, so that on the one hand, the stress caused by the lattice mismatch between the single crystal piezoelectric layer and the substrate may be released, to avoid the fracture of the single crystal piezoelectric layer, and on the other hand, since the support structure layer may play the role of the acoustic wave reflection, when the acoustic wave in the single crystal piezoelectric layer is transmitted to the support structure layer, the acoustic wave is reflected back into the single crystal piezoelectric layer, to reduce energy loss of the acoustic wave.

Based on the above-mentioned surface acoustic wave device structure, an embodiment of the present application further provides an electronic apparatus, including: a surface acoustic wave device having the above-mentioned surface acoustic wave device structure.

It should be noted that the specific type of the electronic apparatus is not limited in the embodiments of the present application, and the electronic apparatus may be a mobile terminal apparatus such as a mobile phone, a game console, a tablet computer and a vehicle-mounted computer, or may also be a Personal Computer (PC), such as a laptop computer and a desktop computer.

According to the surface acoustic wave device structure of this application, the support structure layer is disposed between the single crystal piezoelectric layer and the substrate, so that on the one hand, a stress caused by a lattice mismatch between the single crystal piezoelectric layer and the substrate may be released, to avoid fracture of the single crystal piezoelectric layer, and on the other hand, since the support structure layer may play the role of acoustic wave reflection, when the acoustic wave in the single crystal piezoelectric layer is transmitted to the support structure layer, the acoustic wave is reflected back into the single crystal piezoelectric layer, to reduce energy loss of the acoustic wave.

It should be understood that in this specification, the term “include”, and any other variant thereof are open including, i.e., “including but not limited to”. The term “one embodiment” means “at least one embodiment”; the term “another embodiment” means “at least one other embodiment”. In this specification, the schematic expression of the above terms need not be directed at the same embodiment or example. Furthermore, the specific features, structures, materials or characteristics described may be combined in an appropriate manner in any one or more embodiments or examples. In addition, without contradiction, those skilled in the art may combine and constitute different embodiments or examples described in this specification, and the features in different embodiments or examples.

The above are only preferred embodiments of the present application and are not intended to limit the protection scope of the present application. Any modification, equivalent replacement, improvement, etc. made within the spirit and principle of this application shall be included within the protection scope of this application.

What is claimed is:

1. A surface acoustic wave device structure, comprising:
a substrate, a support structure layer, a single crystal piezoelectric layer and an interdigital transducer which are stacked sequentially,
wherein the support structure layer comprises at least one periodic structure, each of the at least one periodic structure comprises at least one period, and each of the at least one period comprises a first periodic layer and a second periodic layer which are stacked sequentially, a material of the first periodic layer is AlScN, and the first periodic layer is disposed on one side of the second periodic layer away from the substrate.

2. The surface acoustic wave device structure according to claim 1, wherein a material of the second periodic layer is at least one of GaN, AlInN and AlInGaN.

3. The surface acoustic wave device structure according to claim 1, wherein a thickness of the second periodic layer ranges from 10 nm to 30 nm.

4. The surface acoustic wave device structure according to claim 1, wherein a material of the first periodic layer is Al₁₋ₐScₐN, and a Sc component ranges from 0.15 to 0.25.

5. The surface acoustic wave device structure according to claim 1, wherein a lattice constant of the first periodic layer ranges from 3.17 to 3.21.

6. The surface acoustic wave device structure according to claim 1, wherein a lattice constant of the first periodic layer matches that of the second periodic layer.

7. The surface acoustic wave device structure according to claim 1, wherein a thickness of the first periodic layer ranges from 10 nm to 30 nm.

8. The surface acoustic wave device structure according to claim 1, wherein in a same periodic structure, a thickness of the first periodic layer is greater than that of the second periodic layer.

9. The surface acoustic wave device structure according to claim 1, wherein a thickness of the n^{th} periodic structure is less than that of the (n+1)^{th} periodic structure along a direction away from the substrate, and the n is an integer greater than or equal to 1.

10. The surface acoustic wave device structure according to claim 9, wherein a thickness of the first periodic layer of the n^{th} periodic structure is less than that of the first periodic layer of the (n+1)^{th} periodic structure, and a thickness of the second periodic layer of the n^{th} periodic structure is greater than that of the second periodic layer of the (n+1)^{th} periodic structure along the direction away from the substrate.

11. The surface acoustic wave device structure according to claim 10, wherein the thickness of the first periodic layer of the n^{th} periodic structure is less than that of the first periodic layer of the (n+1)^{th} periodic structure within a range of 0 nm to 10 nm; the thickness of the second periodic layer of the n^{th} periodic structure is greater than that of the second periodic layer of the (n+1)^{th} periodic structure within a range of 0 nm to 10 nm.

12. The surface acoustic wave device structure according to claim 1, wherein each of the at least one period further comprises a third periodic layer, and the third periodic layer is disposed between the first periodic layer and the second periodic layer.

13. The surface acoustic wave device structure according to claim 12, wherein a material of the third periodic layer is at least one of AlInN and AlInGaN, and a material component of the third periodic layer is different from that of the second periodic layer.

14. The surface acoustic wave device structure according to claim 12, wherein a thickness of the third periodic layer is less than that of the first periodic layer, and the thickness of the third periodic layer is greater than that of the second periodic layer.

15. The surface acoustic wave device structure according to claim 12, wherein a lattice constant of the third periodic layer matches that of each periodic layer of both the first periodic layer and the second periodic layer.

16. The surface acoustic wave device structure according to claim 1, wherein the substrate is any one of a silicon substrate, a SOI substrate and a silicon substrate of which a surface has silicon dioxide.

17. The surface acoustic wave device structure according to claim 1, wherein the single crystal piezoelectric layer is made of scandium-doped aluminum nitride material.

18. The surface acoustic wave device structure according to claim 1, wherein a thickness of the single crystal piezoelectric layer is greater than 500 nm.

19. An electronic apparatus, comprising a surface acoustic wave device,
wherein the surface acoustic wave device has a surface acoustic wave device structure, comprising:
a substrate, a support structure layer, a single crystal piezoelectric layer; and an interdigital transducer which are stacked sequentially,
wherein the support structure layer comprises at least one periodic structure, each of the at least one periodic structure comprises at least one period, and each of the at least one period comprises a first periodic layer and a second periodic layer which are stacked sequentially, a material of the first periodic layer is AlScN, and the first periodic layer is disposed on one side of the second periodic layer away from the substrate.

20. The electronic apparatus according to claim 19, wherein each of the at least one period further comprises a third periodic layer, and the third periodic layer is disposed between the first periodic layer and the second periodic layer.
